(19) United States
(12) Patent Application Publication
(10) Pub. No.: US 2026/0243609 A1
(43) Pub. Date: Aug. 20, 2026

(54) CURVED CONFORMAL WIRELESS PASSIVE HEAT FLUX SENSOR AND PREPARATION METHOD THEREOF

(71) Applicant: North University of China, Taiyuan (CN)

(72) Inventors: Xiaoling LU, Taiyuan (CN); Lei ZHANG, Taiyuan (CN); Qiulin TAN, Taiyuan (CN); Xinru ZHANG, Taiyuan (CN)

(73) Assignee: North University of China, Taiyuan (CN)

(21) Appl. No.: 19/437,873

(22) Filed: Dec. 31, 2025

(30) Foreign Application Priority Data
Jul. 23, 2025 (CN) 202511018864.0

(51) Int. Cl. G01K 7/02; G01K 1/024; H10N 10/01; H10N 10/817; H10N 10/854

(52) U.S. Cl. CPC G01K 7/021; G01K 1/024; G01K 7/028; H10N 10/01; H10N 10/817; H10N 10/854

(57) ABSTRACT

The present disclosure proposes a curved conformal wireless passive heat flux sensor comprising metal wires disposed sequentially from a bottom upward, a silicon carbide substrate, a sensitive layer, and a thermal resistance layer. The sensitive layer includes a thermopile, an inductor, a capacitor and a microstrip antenna; the thermopile is connected to the capacitor, and the microstrip antenna and the inductor are connected to the other end of the thermopile; the thermal resistance layer has an opening to expose a thermal junction of the thermopile, and the metal wire connects the inductor and the capacitor to form a resonant circuit. The heat flux sensor remains flexible overall, enabling it to conform to the surface of curved components. It features high-temperature resistance and achieves wireless passive transmission of the heat flux signal, thereby resolving issues of difficult wiring and susceptibility to lead breakage in high-temperature, high-rotation environments.

### TECHNICAL FIELD

The present disclosure relates to the technical field of high-temperature sensors, in particular to a curved conformal wireless passive heat flux sensor and a preparation method thereof.

### BACKGROUND

The thermal flux testing of high-temperature, high-rotation, and curved-surface components in aerospace, specialized metallurgy, energy, and power fields imposes increasingly stringent demands on high-temperature-resistant wireless passive heat flux sensors. For instance, the wall temperature of an aero-engine combustion chamber exceeds 1200 °C, with a heat flux density reaching 3MW/m². Addressing requirements such as high-temperature resistance, surface conformality, and wireless passive operation in these fields has become a major constraint limiting advancements in aerospace and related industries.

In recent years, certain progress has been made in heat flux sensor technologies, including silicon-based sensors, flexible sensors, and rigid sensors.

During the course of the present disclosure, the inventor has identified at least the following issues in the prior art: silicon-based sensors fail to operate reliably under high-temperature measurement conditions due to PN junction failure above 300 °C; although flexible sensors achieve curved surface adaptation through materials such as PDMS (polydimethylsiloxane) and carbon nanotube composites, their temperature resistance is generally limited to below 600 °C, and their metal leads are prone to melting under high-temperature environments, resulting in signal transmission failure. Rigid sensors are difficult to conform to complex curved surfaces, leading to measurement inaccuracies. Moreover, most existing heat flux sensors rely on a wired power supply and data transmission, which hinders stable operation on rotating components. This makes in-situ monitoring of heat flux parameters in scenarios such as aero-engines and specialized metallurgical rolls a persistent technical challenge.

### SUMMARY

The present disclosure aims to solve at least one of the technical problems in related technologies to a certain extent.

Therefore, the purpose of this present disclosure is to propose a curved conformal wireless passive heat flux sensor and a preparation method thereof, which can adapt to a high-temperature and high-speed rotation environment and does not rely on a wired power supply.

In order to achieve the above purpose, the first aspect of the present disclosure proposes a curved conformal wireless passive heat flux sensor, including metal wires disposed sequentially from a bottom upward, a silicon carbide substrate, a sensitive layer, and a thermal resistance layer;

the sensitive layer includes a thermopile, an inductor, a capacitor and a microstrip antenna, the thermopile, the inductor, the capacitor and the microstrip antenna are all made of metal by an ink direct writing process; one end of the thermopile is connected to the capacitor, and the microstrip antenna and the inductor are connected to the other end of the thermopile; the thermal resistance layer has at least one opening to expose a thermal junction of the thermopile, the metal wire connects the inductor and the capacitor to form a resonant circuit;

the thermopile is configured to generate a voltage signal corresponding to a heat flux temperature; the resonant circuit is configured to modulate the voltage signal into a high-frequency signal; the microstrip antenna is configured to propagate the high-frequency signal outward in a form of a radio wave.

Based on the advantageous effects of the curved conformal wireless passive heat flux sensor of the present disclosure, the sensor is constructed on a flexible silicon carbide substrate. It incorporates a thermopile, inductor, capacitor, microstrip antenna, and metal wires fabricated via an ink direct-writing process. The heat flux sensor remains flexible overall, enabling it to conform to the surface of curved components while maintaining high-temperature resistance. Furthermore, the inductor, capacitor, and metal wires together form a resonant circuit, which modulates the heat flux signal into a high- frequency signal. This signal is then transmitted over a long distance through the microstrip antenna, thereby achieving wireless passive transmission of the heat flux signal without the need for a wired power supply. This design resolves the issues of difficult wiring and susceptibility to wire breakage in high-temperature, high-rotation environments.

In some embodiments, the thermopile includes multiple pairs of head-to-tail thermocouples, each pair of head-to-tail thermocouples includes a connected first electrode and a second electrode, the first electrode is made of platinum, and the second electrode is made of platinum-rhodium.

In some embodiments, a cross-section of the silicon carbide substrate is a quadrilateral, the thermopile is disposed around three edges of the silicon carbide substrate, the microstrip antenna is disposed on a remaining side of the silicon carbide substrate, and the thermopile and the microstrip antenna surround the inductor and the capacitor.

The second aspect of the present disclosure proposes a preparation method for the curved conformal wireless passive heat flux sensor, including:

Providing a silicon carbide substrate;

preparing a first electrode in the thermopile on a surface of the silicon carbide substrate by the ink direct writing process;

preparing a second electrode in the thermopile on the surface of the silicon carbide substrate by the ink direct writing process;

preparing a resonant circuit and microstrip antenna on the surface of the silicon carbide substrate by the ink direct writing process;

fabricating a thermal resistance layer on the front of the silicon carbide substrate.

Based on the beneficial effects of the preparation method for the curved-surface conformal wireless passive heat flux sensor according to the present disclosure: The heat flux sensor is fabricated on a flexible silicon carbide substrate, and further comprises a thermopile, a resonant circuit, and a microstrip antenna produced via an ink direct writing process. The heat flux sensor retains overall flexibility, allowing it to conform adaptively to the surface of curved components while maintaining high-temperature resistance. Moreover, the resonant circuit modulates the heat flux signal into a high-frequency signal, enabling long-distance transmission through the microstrip antenna without the need for a wired power supply. This achieves wireless passive transmission of the heat flux signal and resolves the issues of difficult wiring and lead breakage in high-temperature, high-rotation environments.

In some embodiments, the provided silicon carbide substrate includes:

Silicon carbide substrate is prepared by chemical vapor deposition.

In some embodiments, preparing the first electrode in the thermopile on the silicon carbide substrate surface by an ink direct writing process includes:

Depositing a platinum metal slurry on a front of the silicon carbide substrate by a nozzle, pre-curing by heating, and sintering to form a dense platinum metal film, and annealing the silicon carbide substrate with platinum metal to obtain the first electrode of the thermopile.

In some embodiments, preparing the second electrode in the thermopile on the surface of the silicon carbide substrate by the ink direct writing process includes:

Depositing a platinum-rhodium metal slurry on the front of the silicon carbide substrate by a nozzle, pre-curing by heating, sintering to form a dense platinum-rhodium metal film, and annealing the silicon carbide substrate with platinum-rhodium metal to obtain the second electrode of the thermopile.

In some embodiments, preparing the resonant circuit and microstrip antenna on the surface of the silicon carbide substrate by the ink direct writing process includes:

Depositing a platinum-rhodium metal slurry on the front of a silicon carbide substrate by a nozzle, pre-curing by heating, and sintering to form a dense platinum-rhodium metal film, annealing the silicon carbide substrate with platinum-rhodium metal to obtain inductor, capacitor and microstrip antenna, the capacitor is connected to one end of the thermopile, and the inductor and microstrip antenna are connected to the other end of the thermopile;

perforating the silicon carbide substrate in an area where the capacitor and inductor are located, depositing the platinum-rhodium metal slurry on a back of the silicon carbide substrate by a nozzle, pre-curing by heating, and sintering to form a dense platinum-rhodium metal film, annealing the silicon carbide substrate with platinum-rhodium metal to obtain a metal wire, the metal wire uses perforation to connect the capacitor and inductor to form a resonant circuit.

In some embodiments, fabricating the thermal resistance layer on the front of the silicon carbide substrate includes:

Depositing the thermal resistance layer on the front of the silicon carbide substrate by a pulsed laser deposition, a material of the thermal resistance layer is alumina.

In some embodiments, annealing treatment is also included, the thermal resistance layer has an opening, the opening is configured to expose a thermal junction of the thermopile.

Additional aspects and advantages of the present disclosure will be given in part in the description below, and part will become apparent from the description below, or learned through the practice of the present disclosure.

### BRIEF DESCRIPTION OF THE DRAWINGS

By reading the detailed description of the preferred implementation method below, various other advantages and benefits will become clear to the general technical personnel in this field. The figures are only used for the purpose of showing the preferred embodiment, and are not considered to be a limitation to the present disclosure. Also, the same reference symbols are configured to represent the same parts throughout the drawings. Among them:

FIG. 1 is a cross-section diagram of the curved conformal wireless passive heat flux sensor proposed in an embodiment of the present disclosure.

FIG. 2 is a schematic diagram of the decomposition structure of the curved conformal wireless passive heat flux sensor proposed in an embodiment of the present disclosure.

FIG. 3 is a positive diagram of the silicon carbide substrate of the curved conformal wireless passive heat flux sensor proposed in an embodiment of the present disclosure.

FIG. 4 is the back of FIG. 3.

FIG. 5 is a schematic diagram of the connection between the sensitive layer and the metal wire of the curved conformal wireless passive heat flux sensor proposed in an embodiment of the present disclosure.

FIG. 6 is a schematic diagram of the surface conformal wireless passive heat flux sensor proposed in an embodiment of the present disclosure.

FIG. 7 is a flow chart of the preparation method for the curved conformal wireless passive heat flux sensor proposed in an embodiment of the present disclosure.

FIG. 8 is a schematic diagram of the preparation process of a curved conformal wireless passive heat flux sensor involved in an embodiment of the present disclosure.

FIG. 9 is a test result of the temperature resistance limit of the curved conformal wireless passive heat flux sensor involved in an embodiment of the present disclosure.

FIG. 10 is a heat flux and output voltage test result of the curved conformal wireless passive heat flux sensor involved in an embodiment of the present disclosure.

FIG. 11 is a dynamic response time test result of the curved conformal wireless passive heat flux sensor involved in an embodiment of the present disclosure.

Marks in the figures:

10-metal wire, 20-silicon carbide substrate, 30-sensitive layer, 40-thermal resistance layer, 31-first electrode, 32-second electrode, 33-microstrip antenna, 34-resonant circuit, 35-thermopile, 41-opening, 341-inductor, 342-capacitor.

### DETAILED DESCRIPTION OF THE EMBODIMENTS

An embodiment of the present disclosure is described in detail below, with an example of the embodiment illustrated in the accompanying drawings, in which the same or similar reference numerals throughout denote the same or similar components or elements having the same or similar functions. The embodiments described below with reference to the accompanying drawings are exemplary and are intended solely to explain the present disclosure, and are not to be construed as limiting the present disclosure. Rather, embodiments of the present disclosure shall include all changes, modifications, and equivalents that fall within the spirit and scope of the appended claims.

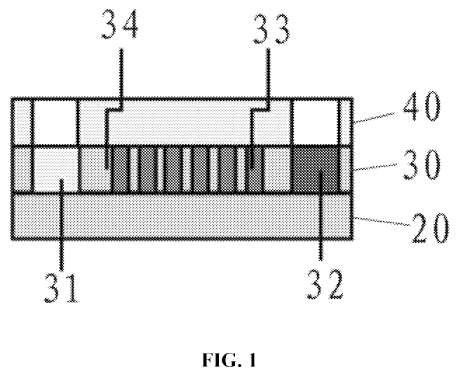

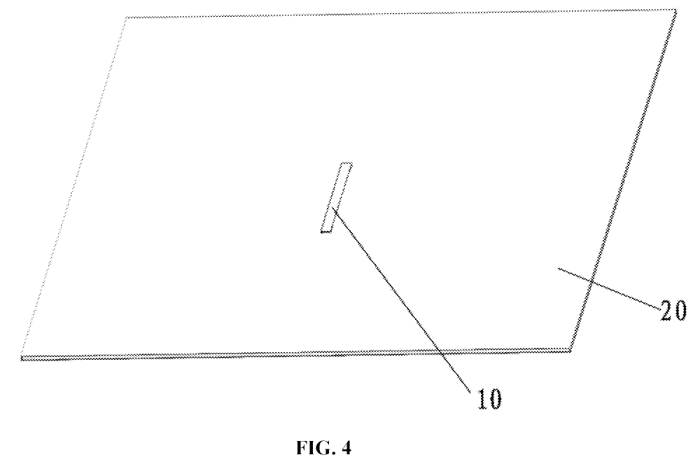

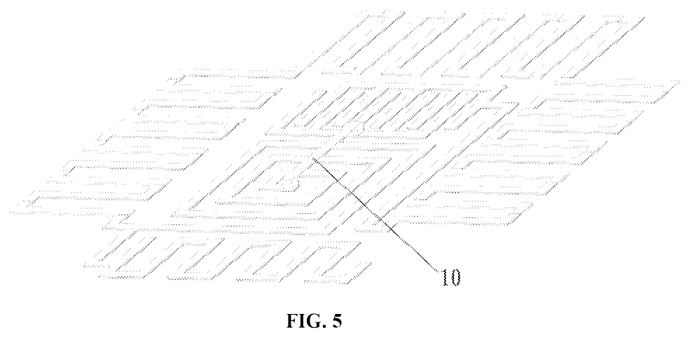

The following refers to FIG. 1 to FIG. 6 to describe the curved conformal wireless passive heat flux sensor according to the embodiment of the present disclosure.

As shown in FIG. 1 to FIG. 5, the curved conformal wireless passive heat flux sensor according to the embodiment of the present disclosure includes metal wires 10 disposed sequentially from a bottom upward, a silicon carbide substrate 20, a sensitive layer 30, and a thermal resistance layer 40.

The sensitive layer 30 includes a thermopile 35, an inductor 341, a capacitor 342, and a microstrip antenna 33, which are all made of metal by an ink direct writing process; one end of the thermopile 35 is connected to the capacitor 342, and the microstrip antenna 33 and the inductor 341 are connected to the other end of the thermopile 35. The thermal resistance layer 40 has at least one opening 41 to expose the thermal junction of the thermopile 35. The metal wire 10 connects the inductor 341 and the capacitor 342 to form a resonant circuit 34.

The thermopile 35 is configured to generate the voltage signal corresponding to the heat flux temperature, the resonant circuit 34 is configured to modulate the voltage signal into a high-frequency signal, and the microstrip antenna 33 is configured to propagate the high-frequency signal outward in the form of radio waves.

The silicon carbide substrate 20 is a flexible material using silicon carbide ceramic fiber, which has the advantages of high thermal conductivity and low thermal expansion coefficient. The size and shape of the silicon carbide substrate 20 are set according to actual needs, which is not limited. For example, the thickness of the silicon carbide substrate 20 is 50-200μm. Ink direct writing process is a technology that directly deposits metal materials in a liquid or semi-solid state. The thermopile 35 is formed by several pairs of thermocouples in series. Thermocouples are made of two different metal materials. The specific materials are selected according to actual needs. For example, high-temperature resistant materials, such as platinum and platinum-rhodium can be used. The inductor 341, the capacitor 342, and the microstrip antenna 33 are made of high-temperature-resistant metal. The specific type of the inductor 341 is set according to the actual needs. For example, the inductor 341 is spiral, and the specific type of the capacitor 342 is set according to the actual needs. For example, the capacitor 342 is an interdigital capacitor. The specific type of the microstrip antenna 33 is set according to actual needs. For example, the microstrip antenna 33 is a square wave shape and can transmit traveling waves. The metal wire 10 also uses high-temperature resistant metal materials, such as platinum-rhodium.

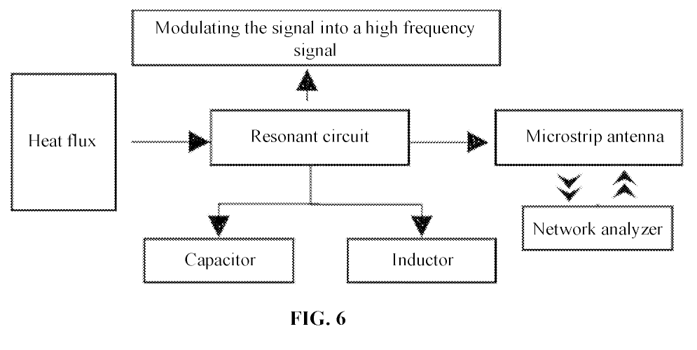

As shown in FIG. 6, the working principle of the conformal wireless passive heat flux sensor according to an embodiment of the present disclosure is as follows: When a vertical heat flux passes through the sensor, a temperature difference is established between the cold and thermal junctions of the thermopile, generating a voltage signal across the thermopile. The resonant circuit 34 modulates this voltage signal into a high‑frequency signal, which is then propagated outward in the form of radio waves by the microstrip antenna 33. Monitoring personnel at a remote location can receive the radio waves containing temperature information via a network analyzer and convert them into temperature values, thereby achieving long-distance monitoring.

According to the embodiment of the present disclosure, the curved conformal wireless passive heat flux sensor is fabricated on a flexible silicon carbide substrate, and further incorporates a thermopile, an inductor, a capacitor, a microstrip antenna, and metal wires produced via the ink direct writing process. The heat flux sensor remains fully flexible overall, allowing it to conform adaptively to the surface of curved components while offering high-temperature resistance. In addition, the inductor, capacitor, and metal wires together constitute a resonant circuit, which modulates the heat flux signal into a high-frequency signal and enables long-range transmission through the microstrip antenna without a wired power supply. This wireless passive transmission of the heat flux signal resolves the issues of difficult wiring and lead breakage in high-temperature, high-rotation environments.

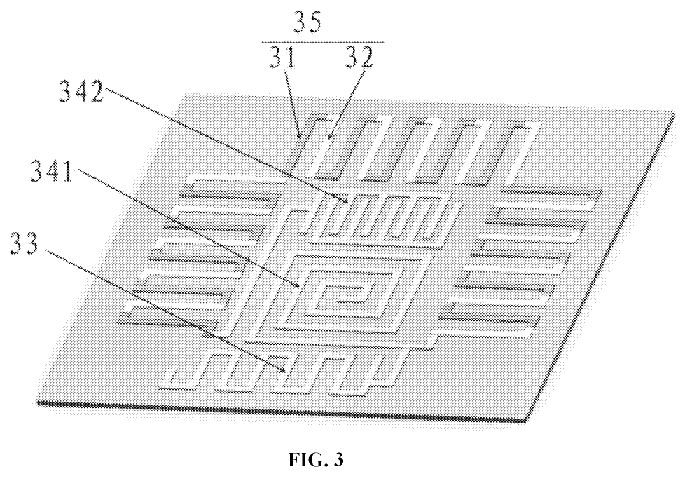

As shown in FIG. 3, the thermopile 35 includes multiple pairs of head-to-tail thermocouples, in which a pair of thermocouples includes a connected first electrode 31 and a second electrode 32. The first electrode 31 is made of platinum, and the second electrode 32 is made of platinum-rhodium. The thermocouple is based on the Seebeck effect, when the junctions of two different metals are at different temperatures, an electromotive force is generated to measure the temperature difference. The logarithm of the thermocouple is set according to the actual measurement temperature, which is not

limited. The first electrode 31 and the second electrode 32 are connected end to end, and the specific type is set according to the actual needs, which is not limited. For example, the first electrode 31 and the second electrode 32 are both L-shaped to adapt to a specific spatial layout. It should be noted that the quadrilateral lining in FIG. 3 is only to facilitate better display of graphics such as thermocouples, which do not exist physically.

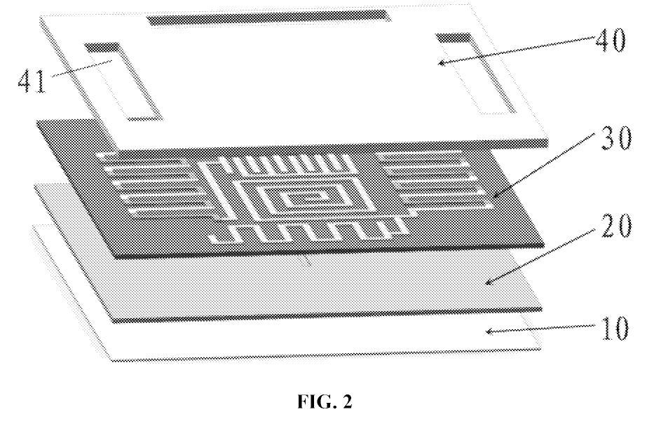

The thermal resistance layer 40 can play an isolation role and reduce the damage of the thermopile by the interference of the external environment. The thermal resistance layer 40 covers the silicon carbide substrate 20 except for the rest of the thermal junction of the thermopile. The thermal resistance layer 40 can be made of alumina. The thermopile junctions covered by the thermal resistance layer 40 are cold junctions, and the exposed junctions are thermal junctions. As shown in FIG. 2, since the thermopile is distributed on the three edges of the silicon carbide substrate 20, the number of openings 41 on the thermal resistance layer 40 is also 3. In one example, the linewidth of the first electrode 31 and the second electrode 32 is 20-50μm, the spacing is 100-200μm, and the thickness of the thermal resistance layer is about 10-50μm.

In one example, the cross section of the silicon carbide substrate 20 is quadrilateral, the thermopile 35 is set around the three sides of the silicon carbide substrate 20, the microstrip antenna 33 is set on the remaining side of the silicon carbide substrate 20, and the thermopile 35 and the microstrip antenna 33 surround the inductor 341 and the capacitor 342. This layout can maximize the use of space, achieve compact design, and effectively collect heat to improve the signal emission performance of microstrip antennas.

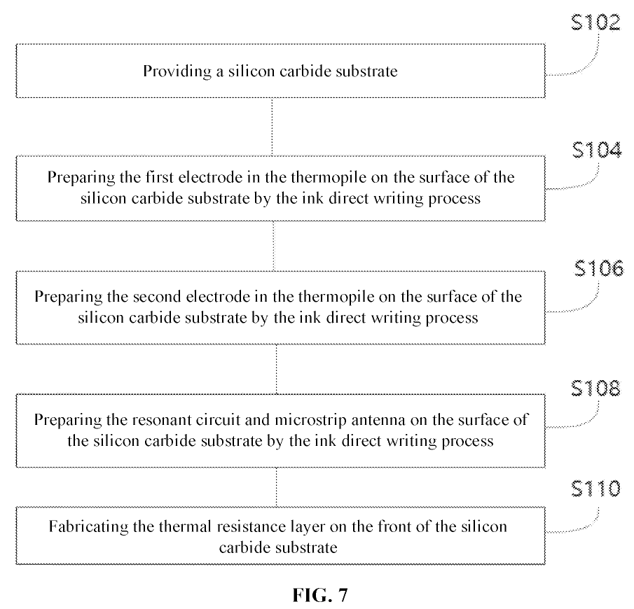

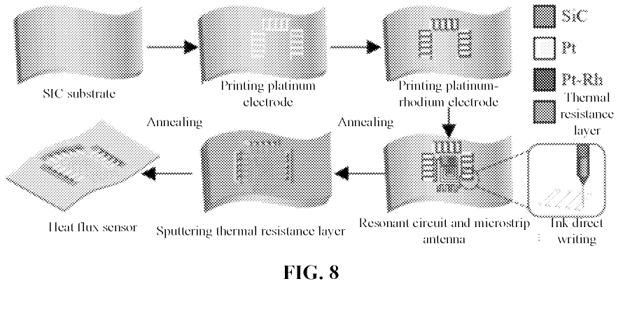

As shown in FIG. 1 to FIG. 8, the embodiment of the present disclosure also proposes a preparation method for the curved conformal wireless passive heat flux sensor used in the above embodiment. The method includes the following steps:

S102, a silicon carbide substrate is provided.

In this embodiment, the silicon carbide substrate can be fabricated by the physical vapor transport method, chemical vapor deposition method, and other methods.

S104, the first electrode in the thermopile is prepared on the surface of the silicon carbide substrate by the ink direct writing process.

In this embodiment, the material of the first electrode is platinum (Pt).

S106, the second electrode in the thermopile is prepared on the surface of the silicon carbide substrate by the ink direct writing process.

In this embodiment, the material of the second electrode is platinum-rhodium (Pt-Rh). Multiple second electrodes are connected with the first electrode to form a thermopile.

S108, the resonant circuit and microstrip antenna are prepared on the surface of the silicon carbide substrate by the ink direct writing process.

In this embodiment, the resonant circuit includes a capacitor, an inductor, and a metal wire. The capacitor and inductor are located on the front of the silicon carbide substrate, and the metal wire is located on the back of the silicon carbide substrate to avoid interference between the metal wire and the capacitor and inductor. The capacitor, inductor, and microstrip antenna are made of platinum-rhodium (Pt-Rh).

S110, a thermal resistance layer is fabricated on the front of the silicon carbide substrate.

In this embodiment, the thermal resistance layer is alumina. As a ceramic material, alumina has good insulation, a high melting point, excellent chemical stability, and its thermal conductivity is relatively low.

According to the preparation method for the curved conformal wireless passive heat flux sensor in the embodiment of the present disclosure, the heat flux sensor is prepared based on the flexible silicon carbide substrate, and the thermopile, resonant circuit, and microstrip antenna are made by the ink direct writing process. The heat flux sensor is still flexible and can be self-adaptively fitted with the surface of the curved component, and has the characteristics of high-temperature resistance. In addition, the resonant circuit can modulate the heat flux signal into a high-frequency signal and realize long-distance transmission through the microstrip antenna, without the need for a wired power supply. The wireless passive transmission of the heat flux signal solves the problem that the lead is difficult to use, and the lead is easy to break in the high-temperature and high-rotation environment.

In some embodiments, the silicon carbide substrate is prepared in S102 includes:

The silicon carbide substrate is prepared by chemical vapor deposition.

The specific implementation method is as follows: In this embodiment, graphite material is selected and cleaned to ensure the purity of the deposited surface; the gas containing silicon and carbon is transported to the reaction chamber through the transport system, the temperature of the reaction chamber is controlled to about 1200-1600 °C, and the high pressure is maintained. Meanwhile, the gas flow rate is adjusted to create an environment suitable for silicon carbide growth. The carbon source gas and the silicon source gas generate silicon carbide and deposit on the surface of the substrate through pyrolysis or gas phase reaction in the reaction chamber. During pyrolysis, the carbon source gas decomposes into carbon atoms and reacts with the silicon source gas. By controlling the reaction conditions and deposition time, the thickness, crystallinity, and orientation of silicon carbide films can be controlled. After the deposition is completed, the reaction chamber is slowly cooled, and then the substrate deposited with silicon carbide is taken out.

In some embodiments, the first electrode in the fabrication of a thermopile on a silicon carbide substrate in S104 via the ink direct writing process includes:

The platinum metal slurry is deposited on the front of the silicon carbide substrate by the nozzle, pre-cured by heating, and sintered to form a dense platinum metal film. The silicon carbide substrate with platinum metal is annealed to obtain the first electrode of the thermopile.

The pre-curing temperature is 150 °C, and the time is 10 min. The sintering temperature is controlled between 900-1350 degrees Celsius to ensure the formation of a dense metal film.

In some embodiments, the second electrode in the thermoelectric stack prepared on the surface of the silicon carbide substrate in S106 via the ink direct writing process includes:

The platinum-rhodium metal slurry is deposited on the front of the silicon carbide substrate by a nozzle, pre-cured by heating, and sintered to form a dense platinum-rhodium metal film. The silicon carbide substrate with platinum-rhodium metal was annealed to obtain the second electrode of the thermopile.

The pre-curing temperature is 150 °C, and the time is 10 min. The sintering temperature is controlled between 900-1350 degrees Celsius to ensure the formation of a dense metal film. Finally, a square thermopile film with an S-shaped connection is obtained, which is set by the interval between the first electrode and the second electrode, and the adjacent metal junction is the thermopile junction.

In some embodiments, a resonant circuit and a microstrip antenna are prepared on the surface of the silicon carbide substrate in S18 via the ink direct writing process, including:

The platinum-rhodium metal slurry is deposited on the front of the silicon carbide substrate by the nozzle, pre-cured by heating, and sintered to form a dense platinum-rhodium metal film. The silicon carbide substrate with platinum-rhodium metal is annealed to obtain the inductor, the capacitor, and the microstrip antenna. The capacitor is connected to one end of the thermopile, and the inductor and the microstrip antenna are connected to the other end of the thermopile;

the silicon carbide substrate in the region where the capacitor and the inductor are located is perforated. The platinum-rhodium metal slurry is deposited on the back of the silicon carbide substrate by a nozzle, pre-cured by heating, and sintered to form a dense platinum-rhodium metal film. The silicon carbide substrate with platinum-rhodium metal is annealed to obtain a metal wire. The metal wire uses a perforation to connect the capacitor and inductor to form a resonant circuit.

The pre-curing temperature is 150 °C, and the time is 10 min. The sintering temperature is controlled between 900-1350 degrees Celsius to ensure the formation of a dense metal film. Perforation can be formed by laser irradiation or reactive ion etching.

In some embodiments, a thermal resistance layer is prepared on the front side of the silicon carbide substrate in S110 includes:

The thermal resistance layer is deposited on the front of the silicon carbide substrate by pulsed laser deposition. The material of the thermal resistance layer was alumina.

The specific embodiment of depositing an alumina thermal resistance layer by pulsed laser deposition process is as follows. The alumina target is installed on the

rotatable target frame. The silicon carbide substrate is ultrasonically cleaned by deionized water, alcohol, and acetone for 5 minutes, respectively. After nitrogen drying, it is fixed on the sample stage; before the formal deposition, the surface of the alumina target is pre-sputtered with a low-energy laser for 3 minutes to remove the oxide layer and contaminants; during the formal deposition, the oxygen flow rate is accurately controlled by the needle valve, and the chamber pressure is adjusted to the range of 0.01-1Pa. The laser energy density is about 1J/cm², and the deposition rate is about 0.5nm/pulse. Quartz crystal microbalance (QCM) is configured to monitor the deposition rate online, and the film thickness of the thermal resistance layer is accurately controlled by the cumulative pulse number. After the deposition is completed, the thermal resistance layer film is annealed at 400 °C/30min in a double-temperature zone tube furnace to ensure that the thermal resistance layer film has high density and stability.

The preparation method for the curved conformal wireless passive heat flux sensor also includes S112, annealing treatment, a thermal resistance layer has an opening, and the opening is configured to expose the thermal junction of the thermopile.

After the above steps, a curved conformal wireless passive heat flux sensor product can be obtained.

The following performance tests are carried out on the curved conformal wireless passive heat flux sensor products obtained according to the above method:

The heat flux sensor product is placed in a thermal environment with a muffle furnace as the core heat source, the muffle furnace temperature is set to rise from room temperature to 1200 °C, and the temperature and voltage data are recorded.

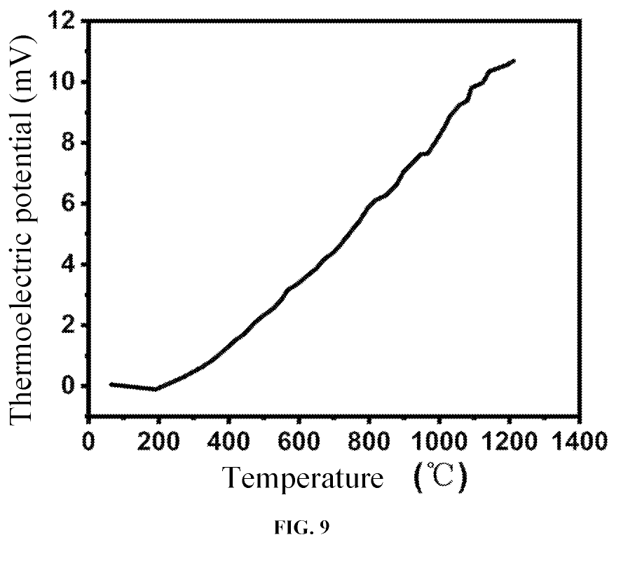

FIG. 9 is a complete data of the temperature limit test, it can be seen that the output thermoelectric power of the heat flux sensor increases with the temperature rising to 1200 °C, and there is no jump or decrease.

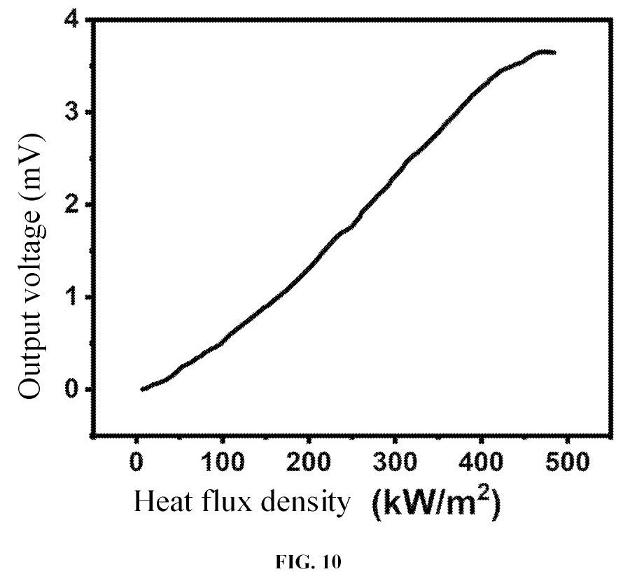

FIG. 10 is a fitting curve of the output voltage of the thin film heat flux sensor and the heat flux density recorded by the standard heat flux meter. It can be seen that the output voltage and the heat flux density are in a quadratic curve distribution.

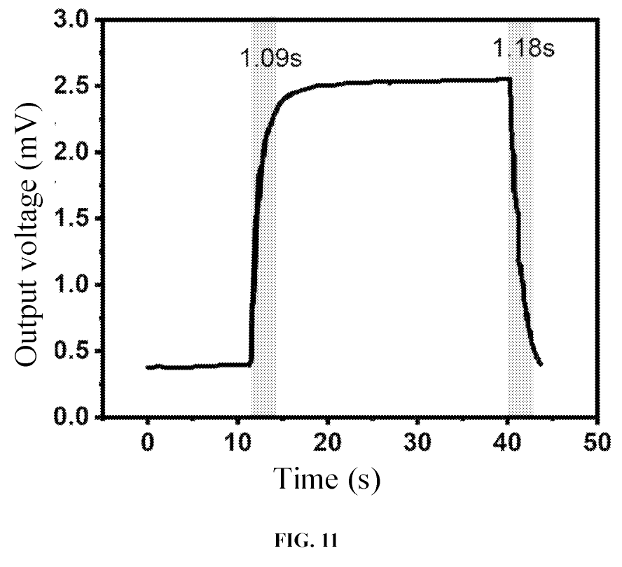

In order to evaluate the dynamic performance of the thin-film heat flux sensor, the response time test is carried out. FIG. 11 is an output voltage of the heat flux sensor recorded by applying step heat flux, the response time is calculated by the time required for the output voltage to reach 90% of its steady-state value, which is 1.09s; the recovery time is defined as the time when the output drops to 90% of the steady-state value, and the recovery time is calculated to be 1.18s.

The high-temperature resistant curved conformal wireless passive heat flux sensor based on silicon carbide prepared by the method of the present disclosure has the following advantages by using thin film technology and radio frequency technology:
1. By adjusting the film thickness gradient and optimizing chemical vapor deposition parameters such as precursor flow rate and annealing temperature, the growth direction of silicon carbide grains is controlled, stress concentration at grain boundaries is reduced, and a dynamic correlation model between interface stress transfer and crack initiation is established to suppress the propagation of high-temperature oxidation cracks.
2. The entire heat flux sensor is fabricated based on a flexible silicon carbide substrate. Through the flexible treatment of the silicon carbide substrate and the ink direct writing process, the metal layer is directly printed, enabling adaptive conformality between the sensor and the surface of curved components. In practical applications, it can be attached to surfaces such as aircraft turbine blades.
3. Using two metal materials, platinum and platinum-rhodium, which possess a high Seebeck coefficient difference, a high-sensitivity thermopile is prepared, addressing the issue of low sensitivity in traditional thin-film thermopile heat flux sensors.
4. The LC resonant circuit is configured to modulate the heat flux signal into a high-frequency signal and achieve long-distance transmission via the microstrip antenna. This enables wireless passive transmission of the heat flux signal and resolves the problems of difficult wiring and susceptibility to wire breakage in high-temperature, high‑rotation environments.
5. The heat flux sensor prepared in the embodiment of the present disclosure offers the advantages of flexibility, high sensitivity, and long-distance transmission capability. These advantages make the sensor more reliable and stable when deployed in harsh environments such as those involving high temperatures and high rotational speeds.

It should be noted that in the description of the present disclosure, terms such as "first" and "second" are used for descriptive purposes only and should not be construed as indicating or implying relative importance. Furthermore, unless otherwise specified, the term "multiple" means two or more.

In the present disclosure, unless otherwise explicitly defined, terms such as “mount,” “connect,” “couple,” “fix,” etc., are to be construed broadly. For example, connections may be fixed or detachable, or may constitute an integral unit; they may be mechanical, electrical, or communicative in nature; they may be direct or indirect via an intermediate medium; and they may refer to an internal connection within a component or an interaction between two components, unless expressly defined otherwise. Those of ordinary skill in the art may understand the specific meanings of these terms in the context of the present disclosure based on the specific circumstances.

In the present disclosure, unless otherwise specified or limited, expressions such as a first feature being “on,” “above,” or “over” a second feature may indicate that the first feature is in direct contact with the second feature or in indirect contact through an intermediate medium. Moreover, such expressions may mean that the first feature is directly above or obliquely above the second feature, or may simply indicate that the horizontal level of the first feature is higher than that of the second feature. Similarly, expressions such as a first feature being “under,” “below,” or “beneath” a second feature may indicate that the first feature is directly below or obliquely below the second feature, or may simply indicate that the horizontal level of the first feature is lower than that of the second feature.

In the description of the present disclosure, orientation or positional relationships indicated by terms such as “left,” “right,” “front,” and “rear” are based on the orientations or positional relationships shown in the accompanying drawings. These terms are used only for convenience in describing the present disclosure and simplifying the description, and are not intended to indicate or imply that the referenced device or component must have a specific orientation or be constructed and operated in a specific orientation. Therefore, they should not be construed as limiting the present disclosure.

Any process or method described in a flowchart or otherwise herein may be understood as representing a module, segment, or portion of code that includes one or more executable instructions for implementing steps of a specific logical function or process. Moreover, preferred embodiments of the present disclosure may include additional embodiments in which functions may be performed in a substantially simultaneous manner or in a reverse order according to the related functions, and are not limited to the order shown or discussed. This should be understood by those skilled in the art to which the embodiments of the present disclosure pertain.

In the description of this specification, reference terms such as “an embodiment,” “some embodiments,” “example,” “specific example,” or “some examples” are intended to indicate that specific features, structures, materials, or characteristics described in connection with the embodiment or example are included in at least one embodiment or example of the present disclosure. In this specification, schematic references to the above terms do not necessarily refer to the same embodiment or example. Furthermore, the described specific features, structures, materials, or characteristics may be combined in any suitable manner in one or more embodiments or examples.

Although embodiments of the present disclosure have been shown and described above, it should be understood that the above embodiments are exemplary and should not be construed as limiting the present disclosure. Those of ordinary skill in the art may make changes, modifications, substitutions, and alterations to the above embodiments within the scope of the present disclosure.

What is claimed is:

1. A curved conformal wireless passive heat flux sensor, comprising metal wires (10) disposed sequentially from a bottom upward, a silicon carbide substrate (20), a sensitive layer (30), and a thermal resistance layer (40);
wherein the sensitive layer (30) comprises a thermopile (35), an inductor (341), a capacitor (342) and a microstrip antenna (33), and wherein the thermopile, the inductor, the capacitor and the microstrip antenna are all made of metal by a ink direct writing process; one end of the thermopile (35) is connected to the capacitor (342), and the microstrip antenna (33) and the inductor (341) are connected to the other end of the thermopile (35); the thermal resistance layer (40) has at least one opening (41) to expose a thermal junction of the thermopile (35), and the metal wire (10) connects the inductor (341) and the capacitor (342) to form a resonant circuit (34);
wherein the thermopile (35) comprises multiple pairs of head-to-tail thermocouples, wherein: each pair of head-to-tail thermocouples comprises a connected first electrode (31) and a second electrode (32); the first electrode (31) is made of platinum, and the second electrode (32) is made of platinum-rhodium; the silicon carbide substrate (20) adopts silicon carbide ceramic fiber; a cross section of the silicon carbide substrate (20) is a quadrilateral; the thermopile (35) is disposed around three edges of the silicon carbide substrate (20); the microstrip antenna (33) is disposed on a remaining side of the silicon carbide substrate (20); and, the thermopile (35) and the microstrip antenna (33) surround the inductor (341) and the capacitor (342); and
the thermopile (35) is configured to generate a voltage signal corresponding to a heat flux temperature; the resonant circuit (34) is configured to modulate the voltage signal into a high-frequency signal; and, the microstrip antenna (33) is configured to propagate the high-frequency signal outward in a form of a radio wave.

2. A preparation method for the curved conformal wireless passive heat flux sensor according to claim 1, comprising:
providing a silicon carbide substrate;
preparing a first electrode in the thermopile on a surface of the silicon carbide substrate by the ink direct writing process;
preparing a second electrode in the thermopile on the surface of the silicon carbide substrate by the ink direct writing process;
preparing a resonant circuit and a microstrip antenna on the surface of the silicon carbide substrate by the ink direct writing process; and
fabricating a thermal resistance layer on a front of the silicon carbide substrate.

3. The preparation method for the curved conformal wireless passive heat flux sensor according to claim 2, wherein the provided silicon carbide substrate comprises:
a silicon carbide substrate prepared by chemical vapor deposition.

4. The preparation method for the curved conformal wireless passive heat flux sensor according to claim 2, wherein preparing the first electrode in the thermopile on the silicon carbide substrate surface by the ink direct writing process comprises:
depositing a platinum metal slurry on a front of the silicon carbide substrate by a nozzle, pre-curing by heating, sintering to form a dense platinum metal film, and annealing the silicon carbide substrate with platinum metal to obtain the first electrode of the thermopile.

5. The preparation method for the curved conformal wireless passive heat flux sensor according to claim 2, wherein preparing the second electrode in the thermopile on the surface of the silicon carbide substrate by the ink direct writing process comprises:
depositing a platinum-rhodium metal slurry on the front of the silicon carbide substrate by a nozzle, pre-curing by heating, sintering to form a dense platinum-rhodium metal film, and annealing the silicon carbide substrate with platinum-rhodium metal to obtain the second electrode of the thermopile.

6. The preparation method for the curved conformal wireless passive heat flux sensor according to claim 2, wherein preparing the resonant circuit and microstrip antenna on the surface of the silicon carbide substrate by the ink direct writing process comprises:
depositing a platinum-rhodium metal slurry on the front of a silicon carbide substrate by a nozzle, pre-curing by heating; sintering to form a dense platinum-rhodium metal film; and annealing the silicon carbide substrate with platinum-rhodium metal to obtain the inductor, capacitor and microstrip antenna; wherein the capacitor is connected to one end of the thermopile, and the inductor and microstrip antenna are connected to the other end of the thermopile;
perforating the silicon carbide substrate in an area where the capacitor and inductor are located; depositing the platinum-rhodium metal slurry on a back of the silicon carbide substrate by a nozzle; pre-curing by heating; and sintering to form a dense platinum-rhodium metal film, thus annealing the silicon carbide substrate with platinum-rhodium metal to obtain a metal wire, wherein the metal wire uses perforation to connect the capacitor and inductor to form a resonant circuit.

7. The preparation method for the curved conformal wireless passive heat flux sensor according to claim 2, wherein fabricating the thermal resistance layer on the front of the silicon carbide substrate comprises:
depositing the thermal resistance layer on the front of the silicon carbide substrate by pulsed laser deposition, wherein the thermal resistance layer comprises alumina.

8. The preparation method for the curved conformal wireless passive heat flux sensor according to claim 7, further comprising an annealing step, wherein the thermal resistance layer has an opening, and the opening is configured to expose a thermal junction of the thermopile.
